(19) United States
(12) Patent Application Publication
(10) Pub. No.: US 2012/0104134 A1
(43) Pub. Date: May 3, 2012

(54) FILL ROLL FOR PRODUCING SEMICONDUCTOR DEVICE

(75) Inventor: Sadahilio Misumi, lbaraki-shi (JP)

(73) Assignee: Nitto Denko Corporation

(21) Appl. No.: 13/131,699

(22) PCT Filed: Nov. 24, 2009
(86) PCT No.: PCT/JP2009/006311

§ 371 Date: May 27, 2011

(30) Foreign Application Priority Data
Dec. 1, 2008 (JP) 2008 306604

(51) Int. Cl. B65H 18/28; H01L 23/00

(52) U.S. Cl. 242/160.4

(57) ABSTRACT

The present invention relates to a semiconductor device manufacturing film roll, comprising a winding core in a cylindrical form, and a semiconductor device manufacturing film which is wound around the winding core into a roll form, wherein the diameter of the winding core is from 7.5 to 15.5 cm.

### TECHNICAL FIELD

The present invention relates to a semiconductor device manufacturing film roll, wherein a semiconductor device manufacturing film, such as a dicing die-bonding film, used in a semiconductor device manufacturing process is wound into a roll form.

### BACKGROUND ART

A semiconductor wafer in which a circuit pattern is formed is diced into semiconductor chips (a dicing step) after the thickness thereof is adjusted as necessary by backside polishing. The semiconductor chip is then fixed onto an adherend such as a lead frame with an adhesive (a die-attaching step), and then transferred to a bonding step. In the die-attaching step, the adhesive has been applied onto the lead frame or the semiconductor chip. However, with this method, it is difficult to make the adhesive layer uniform and a special apparatus and a long period of time become necessary in the application of the adhesive. For this reason, a dicing die-bonding film is proposed that adhesively holds the semiconductor wafer in the dicing step and also imparts an adhesive layer for fixing a chip that is necessary in the mounting step (for example, see Patent Document 1: Japanese Patent Application Laid-Open (JP-A) No. 60-57642).

In the dicing die-bonding film described in Patent Document 1, a pressure-sensitive adhesive layer and an adhesive layer are successively laminated on a supporting base material, and the adhesive layer is formed so that it can be peeled. That is, the dicing die-bonding film is made so that after the semiconductor wafer is diced while being held by the adhesive layer, the semiconductor chip is peeled together with the adhesive layer by stretching the supporting base material, the semiconductor chips are individually recovered, and then they are fixed onto an adherend such as a lead frame with the adhesive layer interposed therebetween.

Good holding strength toward the semiconductor wafer so that a dicing failure, a dimensional error, etc. do not occur and good peeling property in which the semiconductor chip after dicing can be peeled from the supporting base material integrally with the adhesive layer are desired for the adhesive layer of this type of the dicing die-bonding film. However, it is not easy to balance both these characteristics.

In the meantime, as semiconductor devices have been made smaller in thickness and size, the thickness of semiconductor chips has been becoming as thin as 100 μm or less from a conventional thickness of 200 μm. When a semiconductor chip having a thickness of 100 μm or less is used to manufacture a semiconductor device, the use of an adhesive layer in which a thermoplastic resin and a thermosetting resin are together used has been increasing from the viewpoint of the protection of the chip (see, for example, Patent documents 2 and 3 listed up below).

A dicing die-bonding film having such an adhesive layer is stored in a roll state that the film is wound around a winding core before the film is used. The winding of the dicing die-bonding film is attained by bonding a winding-starting end (or edge) of the dicing die-bonding film to be wound onto the winding core, and then rotating the winding core in the direction for the winding. When tensile force for the winding is weak in this case, the bonding sheet is strained so as to be wrinkled and further the winding end face is disturbed. Accordingly, in order to wind up the dicing die-bonding film to make the winding end face in order, the winding is performed while a tensile force having a predetermined value or more is applied thereto.

However, when the film is wound at a strong tensile force for making the winding end face in order, stress is concentrated toward the center of the roll so that, for example, a winding scar is generated in the end region thereof and a dicing die-bonding film wound thereon. When a semiconductor wafer having a thickness of 100 μm or less is mounted on this dicing die-bonding film, there is caused a problem that a step resulting from the winding scar in the film is generated in the semiconductor wafer. When a semiconductor wafer is diced to manufacture semiconductor chips and each of the semiconductor chips is die-attached onto an adherend through an adhesive layer, the adhesive layer cannot sufficiently adhere closely to the semiconductor chip or the adherend if the layer has a winding scar. Thus, the adhesive layer cannot exhibit a sufficient bonding force. As a result, there arises a problem that the semiconductor chip drops out from the adherend.
Patent document 1: JP-A-60-57642
Patent document 2: JP-A-2002-261233
Patent document 3: JP-A-2000-104040

### SUMMARY OF THE INVENTION

### Problems to be Solved by the Invention

The present invention has been made to solve the problems, and an object thereof is to diminish the generation of a winding scar in a semiconductor device manufacturing film, such as a dicing die-bonding film, that is wound into a roll form, thereby providing a semiconductor device manufacturing film roll that is excellent in close adhesiveness and bonding property.

### Means for Solving the Problems

In order to solve the problems in the prior art, the inventors have investigated film rolls for manufacturing a semiconductor device. As a result, the inventors have found out that when the diameter of a winding core around which a semiconductor device manufacturing film is to be wound is controlled into a predetermined value, the film can be wound into a roll form without generating any winding scar in the film. Thus, the invention has been completed.

Accordingly, in order to solve the problems, the film roll for manufacturing a semiconductor device according to the present invention is a semiconductor device manufacturing film roll, comprising a winding core in a cylindrical form, and a semiconductor device manufacturing film which is wound around the winding core into a roll form, wherein the diameter of the winding core is from 7.5 to 15.5 cm.

The winding of a semiconductor device manufacturing film (also referred to as a “film” hereinafter) around a winding core is performed while a tensile force having a predetermined value or more is applied to the film in order to prevent the film from being strained to be wrinkled, or prevent its winding end face from being disturbed. About the film, which is wound around the winding core in this state, stress is concentrated toward the center thereof. In the invention, the diameter of a winding core is set to 7.5 cm or more so as to make the contact area thereof with a film to be wound large, thereby decreasing pressure applied to the unit area thereof to relieve stress concentration. As a result, even when the film roll is stored in the state that the roll is wound around the winding core over a long term, for example, the generation of a winding scar can be prevented in a film region wound on the end of the film. The purpose of setting the diameter of the winding core to 15.5 cm or less is to prevent the following event: the diameter of the semiconductor device manufacturing film roll becomes too large so that the handleability of the film roll is declined.

In the above-mentioned structure, the semiconductor device manufacturing film may have a structure in which a pressure-sensitive adhesive layer, an adhesive layer, and a separator are successively laminated on a base material. According to the invention, also in a dicing die-bonding film having this laminated structure, the generation of a winding scar can be prevented in its pressure-sensitive adhesive layer, its adhesive layer, or its other members. As a result, in a very thin semiconductor wafer mounted on the film, the generation of a step resulting from a winding scar as described above can be prevented.

It is preferred that the Shore A hardness of the adhesive layer is from 10 to 60 in the thickness direction of the layer, and the thickness of the adhesive layer is from 1 to 500 μm. By setting the Shore A hardness and the thickness of the adhesive layer into the respective numerical ranges, the generation of a step resulting from a winding scar in the thickness direction can be further prevented.

In the above-mentioned structure, it is preferred that the semiconductor device manufacturing film is wound around the winding core in the state that a winding tensile force of 20 to 100 N/m is applied thereto. By winding the film around the winding core at a winding tensile force in the numerical range, the sheet can be prevented from being strained to be wrinkled, and further the sheet can be wound without disturbing the winding end face.

In the above-mentioned structure, the diameter of the semiconductor device manufacturing film roll preferably ranges from 8 to 30 cm. By setting the diameter of the film roll to 8 cm or more, the stress that is increasingly concentrated toward the center can be further relieved. By setting the diameter to 30 cm or less, a prevention can be attained against a phenomenon that the winding quantity of the film becomes too large so that an excessive pressure is applied thereto.

The adhesive layer preferably comprises a thermoplastic resin and an inorganic filler.

The adhesive layer preferably comprises a thermosetting resin, and a thermoplastic resin.

The thermoplastic resin is preferably acrylic resin.

The thermosetting resin is preferably at least either one of epoxy resin or phenolic resin. Acrylic resin is small in ionic impurity quantity contained therein and high in heat resistance; thus, the reliability of the semiconductor element (to be obtained) can be surely secured.

### Effects of the Invention

The present invention manufactures the following advantageous effects by the above-mentioned means:

According to the invention, the diameter of a winding core around which a semiconductor device manufacturing film is to be wound is set to 7.5 cm or more, thereby making the contact area of the winding core with the film large. In this way, the pressure applied to the unit area thereof is decreased so that the concentration of stress is relieved. Thus, even when the film roll is stored over a long term, the generation of a winding scar can be prevented in the film. As a result, for example, even when a semiconductor wafer is mounted on the film of the present invention, the generation of a step resulting from a winding scar in the film can be prevented in the semiconductor wafer. Moreover, the film roll of the invention is excellent also in the adhesiveness onto a semiconductor wafer, a semiconductor chip or the like, and can cause the film to exhibit a good bonding property.

### BRIEF DESCRIPTION OF THE DRAWINGS

FIG. 1 is a perspective view illustrating a semiconductor device manufacturing film roll according to an embodiment of the present invention.

FIG. 2 is a schematic sectional view illustrating a laminated structure of the semiconductor device manufacturing film (dicing die-bonding film) according to the embodiment.

FIG. 3 is a schematic sectional view illustrating a laminated structure of another semiconductor device manufacturing film (dicing die-bonding film) according to the embodiment.

FIG. 4 is an explanatory view illustrating a situation that a semiconductor wafer is mounted on a dicing die-bonding film according to an embodiment of the present invention.

FIG. 5 is a perspective view illustrating a situation that the semiconductor wafer is diced.

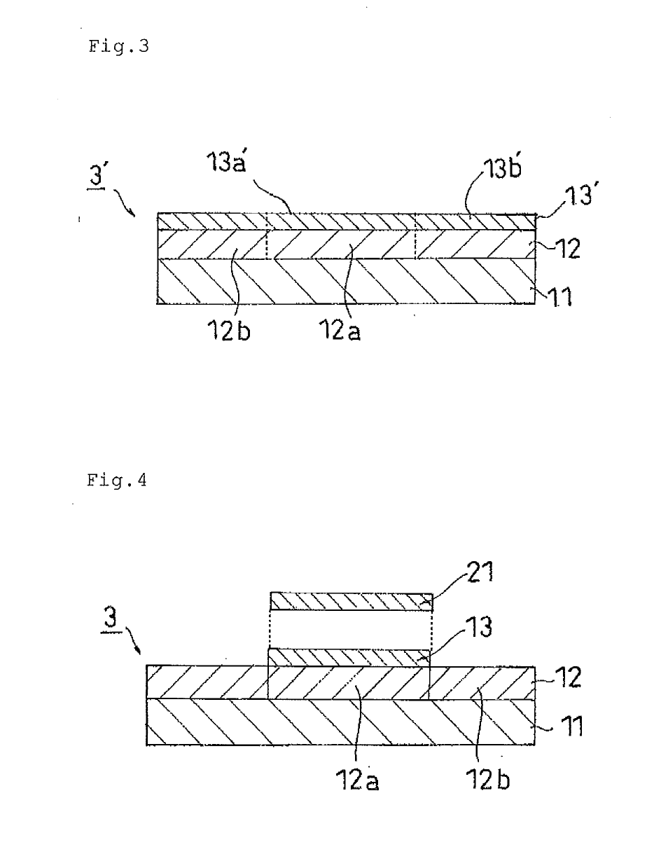

FIG. 3(a) is an explanatory view illustrating a situation that the dicing die-bonding film attached onto a semiconductor wafer is expanded, and FIG. 3(b) is a plan view illustrating a situation that semiconductor chips and a dicing ring are adhered and fixed onto the dicing die-bonding film.

FIG. 7 is a schematic sectional view illustrating an example in which a semiconductor chip is mounted through an adhesive layer of the dicing die-bonding film.

### EMBODIMENTS FOR CARRYING OUT THE INVENTION

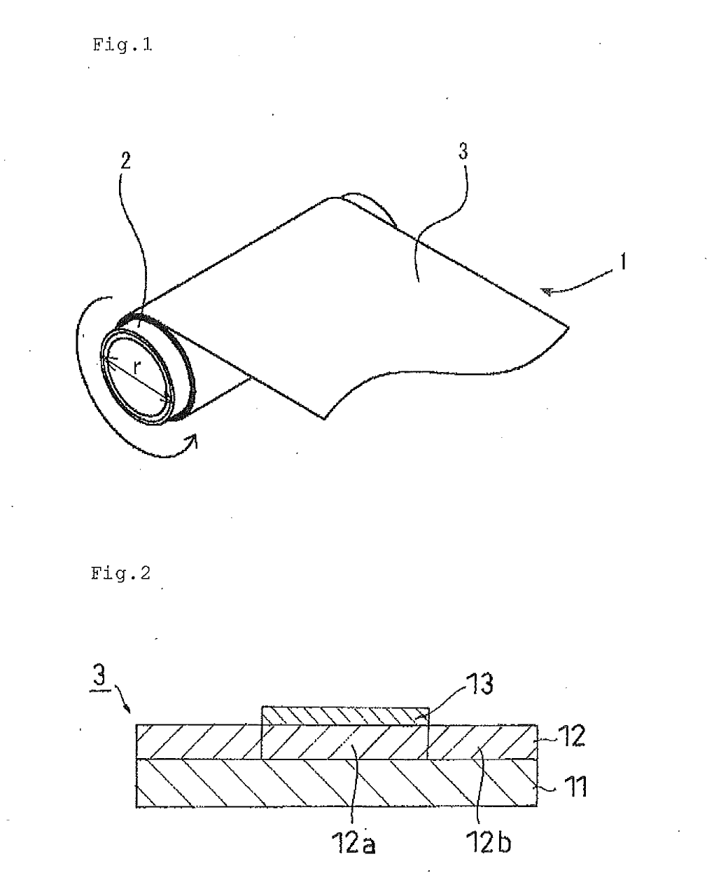

Hereinafter, a description is made about a semiconductor device manufacturing film roll (hereinafter referred to as a “film roll”) according to the present embodiment, giving a dicing die-bonding film as an example of a semiconductor device manufacturing film. FIG. 1 is a perspective view illustrating a schematic structure of the semiconductor device manufacturing film roll according to the embodiment. FIG. 2 is a schematic sectional view illustrating a laminated structure of the dicing die-bonding film as the semiconductor device manufacturing film.

As illustrated in FIG. 1, the film roll 1 according to the embodiment is a roll in which the dicing die-bonding film 3 is wound into a roll form around a cylindrical winding core 2. The winding of the dicing die-bonding film 3 is attained by bonding a winding-starting end of the dicing die-bonding film 3 to be wound onto the winding core 2, and then rotating the winding core 2 in the direction for the winding. At the time of the winding, to the dicing die-bonding film 3 is applied a winding tensile force in the range of 20 to 100 N/m, preferably 25 to 90 N/m, more preferably 30 to 80 N/m. When the winding tensile force is set to 20 N/m or more, the dicing die-bonding film 3 can be prevented from being strained so as to be wrinkled, and the winding end face can be prevented from being disturbed. When the winding tensile force is set to 100 N/m or less, the dicing die-bonding film 3 can be prevented from receiving an excessive tensile force so as to be extended.

The diameter r of the winding core 2 is preferably from 7.5 to 15.5 cm, more preferably from 7.5 to 12.5 cm. When the diameter r is set to 7.5 cm or more, the contact area of the winding core 2 with the dicing die-bonding film 3 is increased so that pressure applied to the unit area thereof can be decreased. As a result, the concentration of stress to the dicing die-bonding film 3 is relieved. When the diameter r is set to 15.5 cm or less, a prevention can be attained against a phenomenon that the diameter of the film roll becomes too large so that the handleability thereof is declined.

The winding core 2 needs to have a shape permitting the dicing die-bonding film 3 to be wound into a roll form. Specifically, the winding core 2 is preferably, for example, a cylindrical winding core. A polygonal column-like winding core is not preferred since stress concentration is generated at any corner of the winding core so that a winding scar is generated in the dicing die-bonding film. The material which constitutes the winding core 2 is not particularly limited, and may be, for example, a metal or a plastic.

The diameter R of the film roll 1 ranges preferably from 8 to 30 cm, more preferably from 8 to 25 cm. When the diameter R is set to 8 cm or more, the stress concentration, which becomes increasingly large toward the center, can be further relieved. When the diameter R is set to 30 cm or less, a prevention can be attained against the phenomenon that the winding amount of the dicing die-bonding film 3 becomes too large so that an excessive pressure is applied thereto.

The dicing die-bonding film 3 has a structure in which a pressure-sensitive adhesive layer 12, an adhesive layer 13 and a separator are successively laminated on a base material 11. The adhesive layer 13 is laminated only in a region on which a semiconductor wafer is to be attached. The winding of the dicing die-bonding film 3 around the winding core 2 is attained in the state that the surface of the base material 11 faces and contacts the surface of the separator. As illustrated in FIG. 3, the dicing die-bonding film according to the embodiment may be a dicing die-bonding film having a structure in which an adhesive layer 13′ is laminated on the entire surface of a pressure-sensitive adhesive layer 12.

The base material 11 has ultraviolet ray transparency and is a strength matrix of the dicing die-bonding films 3, 3′. Examples thereof include polyolefin such as low-density polyethylene, straight chain polyethylene, intermediate-density polyethylene, high-density polyethylene, very low-density polyethylene, random copolymer polypropylene, block copolymer polypropylene, homopolypropylene, polybutene, and polymethylpentene; an ethylene-vinylacetate copolymer; an ionomer resin; an ethylene(meth)acrylic acid copolymer; an ethylene(meth)acrylic acid ester (random or alternating) copolymer; an ethylene-butene copolymer; an ethylene-hexene copolymer; polyurethane; polyester such as polyethyleneterephthalate and polyethylenenaphthalate; polycarbonate; polyetheretherketone; polyimide; polyetherimide; polyamide; whole aromatic polyamides; polyphenylsulfide; aramid (paper); glass; glass cloth; a fluorine resin; polyvinyl chloride; polyvinylidene chloride; a cellulose resin; a silicone resin; metal (foil); and paper.

Further, the material of the base material 11 includes a polymer such as a cross-linked body of the above resins. The above plastic film may be also used unstreched, or may be also used on which a monoaxial or a biaxial stretching treatment is performed depending on necessity. According to resin sheets in which heat shrinkable properties are given by the stretching treatment, etc., the adhesive area of the pressure-sensitive adhesive layer 12 and the adhesive layers 13, 13′ is reduced by thermally shrinking the base material 11 after dicing, and the recovery of the semiconductor chips can be facilitated.

A known surface treatment such as a chemical or physical treatment such as a chromate treatment, ozone exposure, flame exposure, high voltage electric exposure, and an ionized radiation treatment, and a coating treatment by an undercoating agent (for example, a tacky substance described later) can be performed on the surface of the base material 11 in order to improve adhesiveness, holding properties, etc. with the adjacent layer.

The same type or different type of base material can be appropriately selected and used as the base material 11, and a base material in which a plurality of types are blended can be used depending on necessity. Further, a vapor-deposited layer of a conductive substance composed of a metal, an alloy, an oxide thereof, etc. and having a thickness of about 30 to 500 angstrom can be provided on the base material 11 in order to give an antistatic function to the base material 11. The base material 11 may be a single layer or a multi layer of two or more types.

The thickness of the base material 11 can be appropriately decided without limitation particularly. However, it is generally about 5 to 200 μm.

The pressure-sensitive adhesive layer 12 is constituted by containing a ultraviolet-curable pressure sensitive adhesive. The ultraviolet-curable pressure sensitive adhesive can easily decrease its adhesive strength by increasing the degree of crosslinking by irradiation with ultraviolet ray. By radiating only a part 12a corresponding to the semiconductor wafer pasting part of the pressure-sensitive adhesive layer 12 shown in FIG. 2, a difference of the adhesive strength to another part 12b can be also provided.

Also in the dicing die-bonding film 3′ illustrated in FIG. 3, a part 12a corresponding to a part 13a′ onto which a semiconductor wafer is to be attached or bonded can be cured by irradiating the part 12a with ultraviolet rays. In this way, the adhesive strength of the part 12a can be lowered. Since the adhesive layer 13 is attached onto the cured part 12a, where the adhesive strength is lowered, the interface between the part 12a of the pressure-sensitive adhesive layer 12 and the adhesive layer 13 has a nature of being easily peeled off from each other in a pickup step. By contrast, the part not irradiated with the ultraviolet rays has a sufficient adhesive strength, so as to form the part 12b.

As described above, in the pressure-sensitive adhesive layer 12 of the dicing die-bonding film 3 illustrated in FIG. 2, the part 12b can fix a dicing ring. The dicing ring may be, for example, a ring made of a metal such as stainless steel, or a ring made of a resin. In the pressure-sensitive adhesive layer 12 of the dicing die-bonding film 3′ illustrated in FIG. 3, the part 12b made of the uncured ultraviolet-curable pressure-sensitive adhesive has a pressure-sensitive adhesive property to the adhesive layer 13′, so that holding force required when the wafer is diced can be certainly secured. As described herein, the ultraviolet-curable pressure-sensitive adhesive can support the adhesive layer 13′ for fixing and bonding semiconductor chips onto an adherend such as a substrate, with a good balance between the bonding and the peeling.

The ultraviolet-curable pressure-sensitive adhesive having a ultraviolet-curable functional group such as a carbon-carbon double bond, and showing adhesiveness can be used especially without limitation. An example of the ultraviolet-curable pressure-sensitive adhesive includes an adding type ultraviolet-curable pressure-sensitive adhesive, in which a ultraviolet-curable monomer component or oligomer component is compounded into a general pressure-sensitive adhesive such as the above-described acrylic adhesive and rubber adhesive.

An acrylic pressure-sensitive adhesive having an acrylic polymer as a base polymer is preferable as the above-described pressure-sensitive adhesive from the respect of clean washing properties, etc. of electronic parts that dislike contamination such as a semiconductor wafer and glass, with ultrapure water or an organic solvent such as an alcohol.

Examples of the acrylic polymer include acrylic polymers each comprising, as one or more monomer components, one or more selected from alkyl esters of (meth) acrylic acid (for example, linear and branched alkyl esters thereof each having an alkyl group having 1 to 30 carbon atoms, in particular, 4 to 18 carbon atoms, such as methyl ester, ethyl ester, propyl ester, isopropyl ester, butyl ester, isobutyl ester, s-butyl ester, t-butyl ester, pentyl ester, isopentyl ester, hexyl ester, heptyl ester, octyl ester, 2-ethylhexyl ester, isooctyl ester, nonyl ester, decyl ester, isodecyl ester, undecyl ester, dodecyl ester, tridecyl ester, tetradecyl ester, hexadecyl ester, octadecyl ester, and eicosyl ester thereof) and cycloalkyl esters of (meth)acrylic acid (for example, cyclopentyl ester and cyclohexyl ester thereof). The wording “esters of (meth)acrylic acid” means esters of acrylic acid and/or methacrylic acid. All of the words including “(meth)” in connection with the present invention have an equivalent meaning.

The acrylic polymer may optionally contain a unit corresponding to a different monomer component copolymerizable with the above-mentioned alkyl ester of (meth)acrylic acid or cycloalkyl ester thereof in order to improve the cohesive force, heat resistance or some other property of the polymer. Examples of such a monomer component include carboxyl-containing monomers such as acrylic acid, methacrylic acid, carboxyethyl (meth)acrylate, carboxypentyl (meth)acrylate, itaconic acid, maleic acid, fumaric acid, and crotonic acid; acid anhydride monomers such as maleic anhydride, and itaconic anhydride; hydroxyl-containing monomers such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate, and (4-hydroxylmethylcyclohexyl)methyl (meth)acrylate; sulfonic acid group containing monomers such as styrenesulfonic acid, allylsulfonic acid, 2-(meth)acrylamide-2-methylpropanesulfonic acid, (meth) acrylamidepropanesulfonic acid, sulfopropyl (meth)acrylate, and (meth)acryloyloxynaphthalenesulfonic acid; phosphoric acid group containing monomers such as 2-hydroxyethylacryloyl phosphate; acrylamide; and acrylonitrile. These copolymerizable monomer components may be used alone or in combination of two or more thereof. The amount of the copolymerizable monomer(s) to be used is preferably 40% or less by weight of all the monomer components.

Furthermore, the above-described acrylic polymer can also include a multi-functional monomer, etc. as a monomer component for copolymerization depending on the necessity to crosslink. Examples of such multi-functional monomer include hexanedioldi(meth)acrylate, (poly)ethyleneglycoldi(meth)acrylate, (poly)propyleneglycoldi(meth)acrylate, neopentylglycoldi(meth)acrylate, pentaerythritoldi(meth)acrylate, trimethylolpropanetri(meth)acrylate, pentaerythritoltri(meth)acrylate, dipentaerythritolhexa(meth)acrylate, epoxy(meth)acrylate, polyester(meth)acrylate, and urethane(meth)acrylate. One type or two types or more of these multi-functional monomers can be used. An amount to be used of the multi-functional monomer is preferably 30% by weight or less of the entire monomer component from the viewpoint of adhesion characteristics, etc.

The acryl polymer can be obtained by polymerizing a single monomer or a monomer mixture of two or more types. The polymerization can be performed with any of methods such as solution polymerization, emulsifying polymerization, bulk polymerization, and suspension polymerization. From the viewpoint of prevention of contamination to a clean adherend, etc., the content of a low molecular weight substance is preferably small. From this viewpoint, the weight average molecular weight of the acryl polymer is preferably 30,000 or more, and more preferably about 400,000 to 3,000,000.

Further, an external crosslinking agent can be also appropriately adopted in the above-described pressure-sensitive adhesive in order to increase a number average molecular weight of the acrylic polymer that is the base polymer, etc. A specific means of the external crosslinking method includes a method of reacting by adding a so-called crosslinking agent such as a polyisocyanate compound, an epoxy compound, an aziridine compound, and a melamine crosslinking agent. In the case of using an external crosslinking agent, its used amount is determined appropriately by the balance with the base polymer that has to be crosslinked, and further by its use in the pressure-sensitive adhesive agent. Generally, the external crosslinking agent is compounded preferably 5 parts by weight or less, and further preferably 0.1 to 5 parts by weight based on 100 parts by weight of the base polymer. Furthermore, additives such as various conventionally know tackifiers and antioxidants may be used besides the above-described components depending on necessity.

The ultraviolet-curable monomer component to be compounded includes, for example, urethane oligomer, urethane (meth)acrylate, trimethylol propane tri(meth)acrylate, tetramethylol methane tetra(meth)acrylate, pentaerythritol tri(meth)acrylate, pentaerythritol tetra(meth)acrylate, dipentaerythritol monohydroxy penta(meth)acrylate, dipentaerythritol hexa(meth)acrylate, 1,4-butane diol di(meth)acrylate etc. The ultraviolet-curable oligomer component includes various oligomers such as those based on urethane, polyether, polyester, polycarbonate, polybutadiene etc., and their molecular weight is preferably in the range of about 100 to 30000. For the compounded amount of the ultraviolet-curable monomer component or oligomer component, the amount of which the adhesive strength of the pressure-sensitive adhesive layer can be decreased can be determined appropriately depending on the type of the above-described pressure-sensitive adhesive layer. In general, the compounded amount is, for example, 5 to 500 parts by weight relative to 100 parts by weight of the base polymer such as an acrylic polymer constituting the pressure-sensitive adhesive, and preferably about 40 to 150 parts by weight.

The ultraviolet-curable pressure-sensitive adhesive includes an internal ultraviolet-curable pressure-sensitive adhesive using a base polymer having a carbon-carbon double bond in a polymer side chain, in a main chain or at the end of the main chain, in addition to the addition-type ultraviolet-curable pressure-sensitive adhesive described above. The internal ultraviolet-curable pressure-sensitive adhesive does not require incorporation of low-molecular components such as oligomer components etc., or does not contain such compounds in a large amount, and thus the oligomer components etc. do not move with time through the pressure-sensitive adhesive, thus preferably forming the pressure-sensitive adhesive layer having a stabilized layer structure.

A base polymer having a carbon-carbon double bond and having adherability can be used as the base polymer having the above-described carbon-carbon double bond without particular limitation. Abase polymer having an acrylic polymer as a basic skeleton is preferable as such a base polymer. An example of the basic skeleton of an acrylic polymer is the acrylic polymer exemplified above.

The method for introducing a carbon-carbon double bond into any one of the above-mentioned acrylic polymers is not particularly limited, and may be selected from various methods. The introduction of the carbon-carbon double bond into a side chain of the polymer is easier in molecule design. The method is, for example, a method of copolymerizing a monomer having a functional group with an acrylic polymer, and then causing the resultant to condensation-react or addition-react with a compound having a functional group reactive with the above-mentioned functional group and a carbon-carbon double bond while keeping the ultraviolet ray curability of the carbon-carbon double bond.

Examples of a combination of these functional groups include a carboxylic acid group and an epoxy group, a carboxylic acid group and an aziridyl group, and a hydroxyl group and an isocyanate group. Among the combination of these functional groups, a combination of a hydroxyl group and an isocyanate group is preferable due to easiness of tracking the reaction. Further, with the combination of these functional groups, if it is a combination to manufacture the acrylic polymer having the above-described carbon-carbon double bond, the functional group may be located in either side of the acrylic polymer or the above-described compound. However, in the above-described preferred combination, the case that the acrylic polymer has a hydroxyl group and the above-described compound has an isocyanate group is suitable. In this case, examples of the isocyanate compound having a carbon-carbon double bond include methacryloylisocyanate, 2-methacryloyloxyethylisocyanate, and m-isopropenyl-α,α-dimethylbenzylisocyanate. Further, as the acrylic polymer, an acrylic polymer is used in which the hydroxyl group containing the monomer exemplified above, an ether compound such as 2-hydroxyethylvinylether, 4-hydroxybutylvinylether, and diethyleneglycolmonovinylether, etc. are copolymerized.

In the above-described internal-type ultraviolet-ray curing-type pressure-sensitive adhesive, the above-described base polymer having a carbon-carbon double bond (particularly, the acrylic polymer) can be used alone. However, the above-described ultraviolet curable monomer component or oligomer component can be also compounded to a level that the characteristics are deteriorated. The ultraviolet-ray curable oligomer component, etc. are normally in the range of 30 parts by weight, and preferably in the range of 0 to 10 parts by weight based on 100 parts by weight of the base polymer.

For curing with UV rays, a photopolymerization initiator is incorporated into the ultraviolet-curable pressure-sensitive adhesive. The photopolymerization initiator includes, for example, α-ketol compounds such as 4-(2-hydroxyethoxy)phenyl(2-hydroxy-2-propyl)ketone, α-hydroxy-α,α′-dimethyl acetophenone, 2-methyl-2-hydroxypropiophenone, 1-hydroxycyclohexyl phenyl ketone etc.; acetophenone compounds such as methoxyacetophenone, 2,2-dimethoxy-2-phenylacetophenone, 2,2-diethoxyacetophenone, 2-methyl-1-[4-(methylthio)-phenyl]-2-morpholinopropane-1 etc.; benzoin ether compounds such as benzoin ethyl ether, benzoin isopropyl ether, anisoin methyl ether etc.; ketal compounds such as benzyl dimethyl ketal etc.; aromatic sulfonyl chloride compounds such as 2-naphthalene sulfonyl chloride etc.; optically active oxime compounds such as 1-phenone-1,1-propanedione-2-(o-ethoxycarbonyl)oxime etc.; benzophenone compounds such as benzophenone, benzoylbenzoic acid, 3,3′-dimethyl-4-methoxybenzophenone etc.; thioxanthone compounds such as thioxanthone, 2-chlorothioxanthone, 2-methyl thioxanthone, 2,4-dimethyl thioxanthone, isopropyl thioxanthone, 2,4-dichlorothioxanthone, 2,4-diethyl thioxanthone, 2,4-diisopropyl thioxanthone etc.; camphor quinone; halogenated ketone; acyl phosphinoxide; acyl phosphonate etc. The amount of the photopolymerization initiator to be incorporated is for example about 0.05 to 20 parts by weight, based on 100 parts by weight of the base polymer such as acrylic polymer etc. constituting the pressure-sensitive adhesive.

The ultraviolet-curable pressure-sensitive adhesive includes, for example, those disclosed in JP-A 60-196956, such as a rubber-based pressure-sensitive adhesive and an acrylic pressure-sensitive adhesive, comprising an addition-polymerizable compound having two or more unsaturated bonds, a photopolymerizable compound such as alkoxysilane having an epoxy group, and a photopolymerization initiator such as a carbonyl compound, an organic sulfur compound, a peroxide, an amine or an onium salt compound.

The method of forming the part 12a in the pressure-sensitive adhesive layer 12 includes a method of forming the ultraviolet-curable pressure-sensitive adhesive layer 12 on the base material 11 and then radiating the part 12a with ultraviolet ray partially and curing. The partial ultraviolet irradiation can be performed through a photo mask in which a pattern is formed which is corresponding to a part 13b, etc. other than the semiconductor wafer pasting part 13a. Further, examples include a method of radiating in a spot manner and curing, etc. The formation of the ultraviolet-curable pressure-sensitive adhesive layer 12 can be performed by transferring the pressure-sensitive adhesive layer provided on a separator onto the base material 11. The partial ultraviolet curing can be also performed on the ultraviolet-curable pressure-sensitive adhesive layer 12 provided on the separator.

In the pressure-sensitive adhesive layer 12 of the dicing die-bonding film 3, the ultraviolet irradiation may be performed on a part of the pressure-sensitive adhesive layer 12 so that the adhesive strength of the part 12a becomes smaller than the adhesive strength of other parts 12b. That is, the part 12a in which the adhesive strength is decreased can be formed by using those in which the entire or a portion of the part other than the part corresponding to the semiconductor wafer pasting part 13a on at least one face of the base material 11 is shaded, forming the ultraviolet-curable pressure-sensitive adhesive layer 12 onto this, then radiating ultraviolet ray, and curing the part corresponding the semiconductor wafer pasting part 13a. The shading material that can be a photo mask on a supporting film can be manufactured by printing, vapor deposition, etc. Accordingly, the dicing die-bonding film 3 of the present invention can be manufactured with efficiency.

When an impediment to curing due to oxygen occurs during the ultraviolet irradiation, it is desirable to shut off oxygen (air) from the surface of the ultraviolet-ray curing-type pressure-sensitive adhesive layer 12. Examples of the shut-off method include a method of coating the surface of the pressure-sensitive adhesive layer 12 with a separator and a method of conducting irradiation with ultraviolet rays in a nitrogen gas atmosphere.

The thickness of the pressure-sensitive adhesive layer 12 is not particularly limited. However, it is preferably about 1 to 50 μm from the viewpoints of compatibility of chipping prevention of the chip cut face and holding the fixation of the adhesive layer 13, etc. It is preferably 2 to 30 μm, and further preferably 5 to 25 p.m.

The adhesive layers 13 and 13′ are each a layer having an adhesive function, and the constituting material thereof may be a combination of a thermoplastic resin and a thermosetting resin, or may be a thermoplastic resin alone.

The Shore A hardness of each of the adhesive layers 13 and 13′ in the thickness direction thereof is preferably from 10 to 60, more preferably from 15 to 55, in particular preferably from 20 to 50. The Shore A hardness is a value obtained by measuring, on the basis of JIS K 6253, a test piece having a thickness of 10 mm at its point having a distance of 15 mm from an end of the test piece, using a type A durometer.

Examples of the thermoplastic resin include natural rubber, butyl rubber, isoprene rubber, chloroprene rubber, ethylene/vinyl acetate copolymer, ethylene/acrylic acid copolymer, ethylene/acrylic ester copolymer, polybutadiene resin, polycarbonate resin, thermoplastic polyimide resin, polyamide resins such as 6-nylon (registered trademark) and 6,6-nylon (registered trademark), phenoxy resin, acrylic resin, saturated polyester resins such as PET and PBT, polyamideimide resin, and fluorine-contained resin. These thermoplastic resins may be used alone or in combination of two or more thereof. Of these thermoplastic resins, acrylic resin is particularly preferable since the resin contains ionic impurities in only a small amount and has a high heat resistance so as to make it possible to ensure the reliability of the semiconductor element.

The acrylic resin is not limited to any especial kind, and may be, for example, a polymer comprising, as a component or components, one or more esters of acrylic acid or methacrylic acid having a linear or branched alkyl group having 30 or less carbon atoms, in particular, 4 to 18 carbon atoms. Examples of the alkyl group include methyl, ethyl, propyl, isopropyl, n-butyl, t-butyl, isobutyl, amyl, isoamyl, hexyl, heptyl, cyclohexyl, 2-ethylhexyl, octyl, isooctyl, nonyl, isononyl, decyl, isodecyl, undecyl, lauryl, tridecyl, tetradecyl, stearyl, octadecyl, and dodecyl groups.

A different monomer which constitutes the above-mentioned polymer is not limited to any especial kind, and examples thereof include carboxyl-containing monomers such as acrylic acid, methacrylic acid, carboxyethyl acrylate, carboxypentyl acrylate, itaconic acid, maleic acid, fumaric acid, and crotonic acid; acid anhydride monomers such as maleic anhydride and itaconic anhydride; hydroxyl-containing monomers such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate, and (4-hydroxymethylcyclohexyl)methylacrylate; monomers which contain a sulfonic acid group, such as styrenesulfonic acid, allylsulfonic acid, 2-(meth)acrylamide-2-methylpropanesulfonic acid, (meth)acrylamidepropane sulfonic acid, sulfopropyl (meth)acrylate, and (meth) acryloyloxynaphthalenesulfonic acid; and monomers which contain a phosphoric acid group, such as 2-hydroxyethylacryloyl phosphate.

Examples of the above-described thermosetting resin include a phenol resin, an amino resin, an unsaturated polyester resin, an epoxy resin, a polyurethane resin, a silicone resin, and a thermosetting polyimide resin. These resins can be used alone, or two or more of them can be used together. Particularly, an epoxy resin is preferable having fewer ionic impurities, etc. that corrode a semiconductor element. Further, a phenol resin is preferable as a curing agent of the epoxy resin.

The above-described epoxy resin is not particularly limited as long as it is generally used as an adhesive composition, and examples thereof include a bifunctional epoxy resin and a multifunctional epoxy resin of a bisphenol A type, a bisphenol F type, a bisphenol S type, a brominated bisphenol A type, a hydrogenated bisphenol A type, a bisphenol AF type, a bisphenyl type, a naphthalene type, a fluorene type, a phenol novolak type, an o-cresol novolak type, a trishydroxyphenylmethane type, a tetraphenylolethane type, etc. and an epoxy resin of a hydantoin type, a trisglycidylisocyanurate type, a glycidylamine type, etc. These can be used alone, or two or more of them can be used together. Among these epoxy resins, a novolak type epoxy resin, a biphenyl type epoxy resin, a trishydroxyphenylmethane type resin, and a tetraphenylolethane type epoxy resin are particularly preferable. This is because these epoxy resins have rich reactivity with the phenol resin as a curing agent and are excellent in heat resistance, etc.

The phenol resin is a resin acting as a curing agent for the epoxy resin. Examples thereof include Novolak type phenol resins such as phenol Novolak resin, phenol aralkyl resin, cresol Novolak resin, tert-butylphenol Novolak resin and nonylphenol Novolak resin; resol type phenol resins; and polyoxystyrenes such as poly(p-oxystyrene). These may be used alone or in combination of two or more thereof. Among these phenol resins, phenol Novolak resin and phenol aralkyl resin are particularly preferable, since the connection reliability of the semiconductor device can be improved.

About the blend ratio between the epoxy resin and the phenol resin, for example, the phenol resin is blended with the epoxy resin in such a manner that the hydroxyl groups in the phenol resin is preferably from 0.5 to 2.0 equivalents, more preferably from 0.8 to 1.2 equivalents per equivalent of the epoxy groups in the epoxy resin component. If the blend ratio between the two is out of the range, curing reaction therebetween does not advance sufficiently so that properties of the cured epoxy resin easily deteriorate.

Moreover, in the present embodiment, adhesive layers 13, 13′ using an epoxy resin, a phenol resin, and an acrylic resin are particularly preferable. Because these resins have fewer ionic impurities and high heat resistance, the reliability of the semiconductor element can be secured. For the compounding ratio of this case, a mixed amount of the epoxy resin and the phenol resin is 10 to 200 parts by weight based on 100 parts by weight of the acrylic resin component.

In order to crosslink the adhesive layers 13, 13′ of the present embodiment to a certain degree in advance, a multifunctional compound that reacts with the functional group, etc. of the molecular chain end of a polymer may be added as a crosslinking agent during production. Thus, the adhesion characteristics under high temperature are improved, and the improvement of the heat resistance can be attempted.

A conventional known crosslinking agent can be adopted as the above-described crosslinking agent. Particularly, a polyisocyanate compound such as tolylenediisocyanate, diphenylmethanediisocyanate, p-phenylenediisocyanate, 1,5-naphthalenediisocyanate, and an adduct of a polyhydric alcohol and diisocyanate are more preferable. The amount to be used of the crosslinking agent is normally preferably set to 0.05 to 7 parts by weight based on 100 parts by weight of the above-described polymer. When the amount of the crosslinking agent is more than 7 parts by weight, it is not preferable because the adhering strength decreases. On the other hand, when it is less than 0.05 part by weight, it is not preferable because the cohesive strength becomes insufficient. Further, other multifunctional compounds such as an epoxy resin may be contained together with such a polyisocyanate compound depending on necessity.

Inorganic fillers may be compounded into the adhesive layers 13, 13′ depending on its use. Compounding inorganic fillers enable to impart a conductivity, to improve a thermal conductivity, and to adjust an elastic modulus. Examples of the inorganic fillers include various inorganic powders made of the following: a ceramic such as silica, clay, plaster, calcium carbonate, barium sulfate, aluminum oxide, beryllium oxide, silicon carbide or silicon nitride; a metal such as aluminum, copper, silver, gold, nickel, chromium, bell, tin, zinc, palladium or solder, or an alloy thereof; and carbon. These may be used alone or in combination of two or more thereof. Among these, silica, in particular fused silica is preferably used. The average particle size of the inorganic filler materials is preferably in the range of 0.1 to 80 μm,

The amount of the inorganic filler to be incorporated is preferably set into the range of 0 to 80 parts by weight, more preferably 0 to 70 parts by weight for 100 parts by weight of the organic resin components.

If necessary, other additives besides the inorganic filler may be incorporated into the adhesive layers 13, 13′. Examples thereof include a flame retardant, a silane coupling agent, and an ion trapping agent. Examples of the flame retardant include antimony trioxide, antimony pentaoxide, and brominated epoxy resin. These may be used alone or in combination of two or more thereof. Examples of the silane coupling agent include β-(3,4-epoxycyclohexyl)ethyltrimethoxysilane, γ-glycidoxypropyltrimethoxysilane, and γ-glycidoxypropylmethyldiethoxysilane. These may be used alone or in combination of two or more thereof. Examples of the ion trapping agent include hydrotalcite and bismuth hydroxide. These may be used alone or in combination of two or more thereof.

The thickness of the adhesive layer 13 is not particularly limited. However, it is about 5 to 100 μm, and preferably about 5 to 50 μm.

The dicing die-bonding films 3, 3′ can be made to have an antistatic function. Accordingly, the circuit can be prevented from breaking down due to the generation of electrostatic energy during adhesion and peeling thereof and charging of a workpiece (a semiconductor wafer, etc.) by electrostatic energy or the like. Imparting the antistatic function can be performed with an appropriate manner such as a method of adding an antistatic agent or a conductive substance to the base material 11, the pressure-sensitive adhesive layer 12, and the adhesive layer 13 and providing of a conductive layer composed of a charge-transfer complex, a metal film, etc. to the base material 11. These methods are preferably a method of which an impurity ion is difficult to generate, which impurity ion might change quality of the semiconductor wafer. Examples of the conductive substance (conductive filler) to be compounded for the purpose of imparting conductivity, improving thermal conductivity, etc. include a sphere-shaped, a needle-shaped, a flake-shaped metal powder such as silver, aluminum, gold, copper, nickel, and conductive alloy; a metal oxide such as alumina; amorphous carbon black, and graphite. However, the adhesive layers 13, 13′ are preferably non-conductive from the viewpoint of having no electric leakage.

The adhesive layers 13, 13′ of the dicing die-bonding films 3, 3′ are preferably protected by a separator (not shown). The separator has a function as a protecting material that protects the adhesive layers 13, 13′ until they are practically used. Further, the separator can be used as a supporting base material when transferring the adhesive layers 13, 13′ to the pressure-sensitive adhesive layer 12. The separator is peeled when pasting a workpiece onto the adhesive layers 13, 13′ of the dicing die-bonding film. Polyethylenetelephthalate (PET), polyethylene, polypropylene, a plastic film, a paper, etc. whose surface is coated with a peeling agent such as a fluorine based peeling agent and a long chain alkylacrylate based peeling agent can be also used as the separator.

The following describes a method for manufacturing a semiconductor device, using the film roll 1 according to the present embodiment. First, the dicing die-bonding film 3 is cut from the film roll 1 and is taken out therefrom, and then the separator is peeled off therefrom.

Next, as illustrated in FIG. 4, a semiconductor wafer 21 is pressure-attached onto the adhesive layer 13 of the dicing die-bonding film 3, so that the semiconductor wafer 21 is bonded and held thereon so as to be fixed thereon (mounting step). The present step is performed while the wafer is pressed/pressured by means of a pressing/pressuring means, such as a press roll.

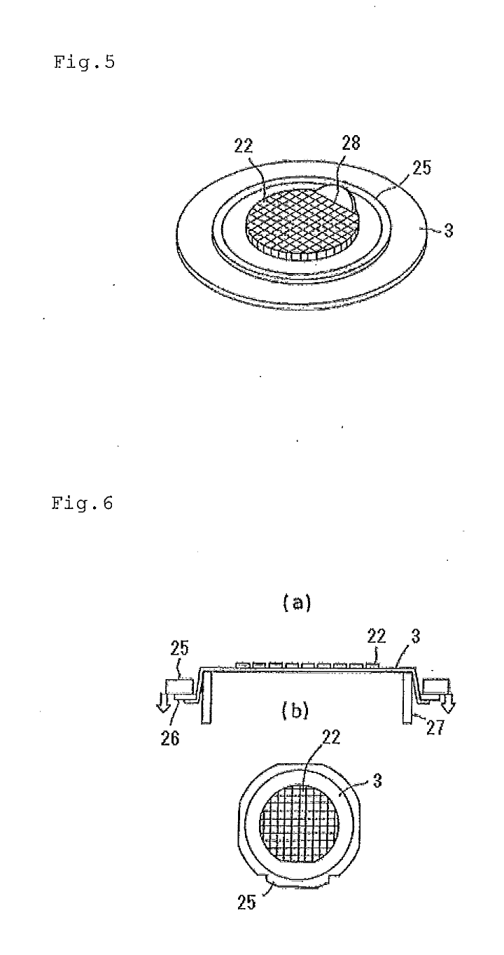

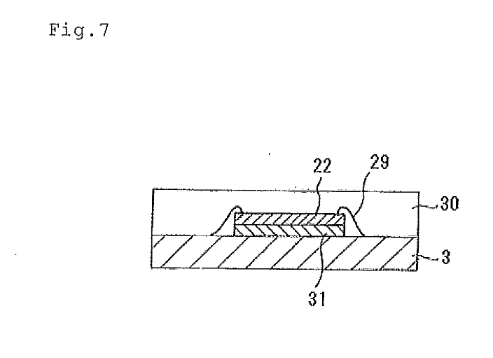

Next, as shown in FIG. 5, the dicing of the semiconductor wafer 21 is performed. Accordingly, the dicing is a step wherein the semiconductor wafer 21 is cut into a prescribed size and individualized, and a semiconductor chip 22 is manufactured. The dicing is performed following a normal method from the circuit face side of the semiconductor wafer 21, for example. The dicing apparatus used in the present step is not particularly limited, and a conventionally known apparatus can be used. Further, because the semiconductor wafer 21 is adhered and fixed by the dicing die-bonding film 3, chip crack and chip fly can be suppressed, and at the same time the damage of the semiconductor wafer 21 can be also suppressed. In the dicing, the cutting may be performed to such a degree that a dicing blade 28 reaches the pressure-sensitive adhesive layer 12.

Next, as illustrated in FIGS. 6, the dicing die-bonding film 3 is expanded (see FIGS. 6(a) and 6(b)). FIG. 6(a) is an explanatory view illustrating a situation that the dicing die-bonding film 3 attached onto the semiconductor wafer 21 is expanded, and FIG. 6(b) is a plan view illustrating a situation that a plurality of semiconductor chips 22 and a dicing ring 25 are adhered and fixed onto the adhesive layer 13. The plurality of semiconductor chips 22, which are formed by dicing the semiconductor wafer 21, are adhered and fixed onto the adhesive layer 13. Outside a region where the individual semiconductor chips 22 are formed, the dicing ring 25 is adhered and fixed on the pressure-sensitive adhesive layer 12 so as to be located, across a predetermined region, away from a region where the plurality of semiconductor chips 22 are adhered and fixed. The expanding is performed by use of a conventional expanding device. The expanding device has a doughnut-form outside ring 26 capable of pushing down the dicing die-bonding film 3 through the dicing ring 25, and an inner ring 27, smaller in diameter than the outside ring 26, for supporting the dicing die-bonding film 3.

The expanding is performed as follows: first, the outside ring 26 is positioned over the inside ring 27 to have a sufficient distance from the inside ring 27 to such a degree that the dicing die-bonding film 3 can be interposed between the two rings. Next, the dicing die-bonding film 3 on which the semiconductor chips 22 and the dicing ring 25 are adhered and fixed is interposed between the outside ring 26 and the inside ring 27. At this time, the film 3 is set in such a manner that the region where the semiconductor chips 22 are adhered and fixed is positioned at the central part of the inside ring 27. Thereafter, the outside ring 26 is shifted downward along the inside ring 27, and simultaneously causes the dicing ring 25 to be pushed down. When the dicing ring 25 is pushed down, the dicing die-bonding film 3 is stretched by a difference in height between the dicing ring and the inside ring. In this way, the expanding is conducted. The purpose of the expanding is to prevent the semiconductor chips 22 from contacting each other so as to be damaged when the chips are picked up.

Next, pickup of the semiconductor chip 22 is performed in order to peel off a semiconductor chip 22 that is adhered and fixed to the dicing die-bonding film 3. The method of picking up is not particularly limited, and conventionally known various methods can be adopted. Examples include a method of pushing up the individual semiconductor chip 22 from the dicing die-bonding film 3 side with a needle and picking up the pushed semiconductor chip 22 with a picking-up apparatus.

The semiconductor chip 22 picked up is adhered and fixed to an adherend 23 through the adhesive layer 31 interposed therebetween (die attaching). The adherend 23 is mounted on a heat block. The adhesive layer 13 according to the present embodiment is a layer in which the generation of a step resulting from a winding scar is restrained. Thus, the die-attachment can be performed in the state that a sufficient adhesiveness of the adhesive layer 13 to the adherend 23 is certainly secured. As a result, the semiconductor chip 22 can be satisfactorily adhered onto the adherend 23. Conditions for the die-attachment are not particularly limited, and may be appropriately set as the need arises. Examples of the adherend 23 include a lead frame, a TAB film, a substrate, and a semiconductor chip separately manufactured and the like. The adherend 23 may be a deformable adherend that are easily deformed, or may be a non-deformable adherend (a semiconductor wafer, etc.) that is difficult to deform, for example.

A conventionally known substrate can be used as the substrate. Further, a metal lead frame such as a Cu lead frame and a 42 Alloy lead frame and an organic substrate composed of glass epoxy, BT (bismaleimide-triazine), and polyimide can be used as the lead frame. However, the present invention is not limited to this, and includes a circuit substrate that can be used by mounting a semiconductor chip and electrically connecting with the semiconductor chip.

When the adhesive layer 13 is a thermosetting type die-bonding film, the semiconductor chip 22 is adhered and fixed onto the adherend 23 by heat-curing to improve the heat resistance strength. Here, a product in which the semiconductor chip 22 is adhered and fixed onto a substrate etc. through the adhesive layer 31 interposed therebetween can be subjected to a reflow step. After that, wire bonding is performed by electrically connecting the tip of a terminal part (inner lead) of the substrate and an electrode pad (not shown) on the semiconductor chip 22 with a bonding wire 29, and furthermore, the semiconductor chip is sealed with a sealing resin 30, and the sealing resin 30 is after cured. Accordingly, the semiconductor device according to the present embodiment is manufactured.

As described above, about the dicing die-bonding film taken out from the film roll according to the present embodiment, the generation of a step resulting from a winding scar is restrained in the adhesive layer 13. Thus, the semiconductor chip 22 can be satisfactorily bonded onto the adherend 23 without the dropout of the chip 22 from the adherend 23. As a result, when the dicing die-bonding film according to the present embodiment is applied to the manufacturing of semiconductor devices, the manufacturing yield of the semiconductor devices can be decreased.

### EXAMPLES

Preferred examples of this invention are demonstratively described in detail hereinafter. However, materials, blend amounts and others that are described in the examples are mere explanatory examples unless a restrictive description is made thereabout; thus, it is not intended that the scope of this invention is not restricted only to a scope based on the materials and the others.

### Example 1

Into methyl ethyl ketone were dissolved 100 parts by weight of an acrylic ester based polymer made mainly of ethyl acrylate/methyl methacrylate (PARACHRON W-197CM, manufactured by Negami Chemical Industrial Co., Ltd.), 3 parts by weight of a polyfunctional isocyanate based crosslinking agent, 23 parts by weight of an epoxy resin (EPICOAT 1004, manufactured by Japan Epoxy Resins Co., Ltd.), 6 parts by weight of a phenolic resin (MILEX XLC-LL, manufactured by Mitsui Chemicals, Inc.), and 60 parts by weight of spherical silica (S0-25R, manufactured by Admatechs Co., Ltd.), so as to prepare a solution of an adhesive composition, the concentration of which was 20% by weight.

This adhesive composition solution was painted onto a releasing-treated film (core material) as a peeling liner, consisting of a polyethylene terephthalate film (thickness: 50 μm) subjected to silicone-releasing treatment, and then the resultant was dried at 120° C. for 3 minutes. In this way, an adhesive layer having a thickness of 25 μm was formed on the releasing-treated film.

Next, a solution of an acrylic pressure-sensitive adhesive composition was painted onto a base material, consisting of a polyolefin film having a thickness of 100 μm, and then dried to form a pressure-sensitive adhesive layer having a thickness of 7 μm. In this way, a dicing film was formed (MD-107G, manufactured by Nitto Denko Corporation).

The acrylic pressure-sensitive adhesive solution was prepared as follows: first, butyl acrylate, ethyl acrylate, 2-hydroxy acrylate, and acrylic acid were copolymerized at a ratio by weight of 60/40/4/1 to yield an acrylic polymer having a weight average molecular weight of 800,000. Next, into 100 parts by weight of this acrylic polymer were incorporated 0.5 parts by weight of a polyfunctional epoxy based crosslinking agent as a crosslinking agent, 90 parts by weight of dipentaerythritol monohydroxypentaacrylate as a photopolymerizable compound, and 5 parts by weight of α-hydroxycyclohexyl phenyl ketone as a photopolymerization initiator, and then these components were evenly dissolved into toluene as an organic solvent. In this way, the acrylic pressure-sensitive adhesive solution was prepared.

Subsequently, the adhesive layer on the releasing-treated film was cut out into the form of a circle having a diameter of 330 mm, and this circular adhesive layer was attached onto the pressure-sensitive adhesive layer of the above-mentioned dicing film. Conditions for the attaching were as follows: a laminating temperature of 40° C., and a linear pressure of 3.0 kgf/cm. In this way, a dicing die-bonding film according to the present example was manufactured.

The same 300 dicing die-bonding films as described above were wound around a winding core having a diameter of 3 inches (7.62 cm). The winding tensile force applied to the dicing die-bonding films at this time was set to 25 N/m. The diameter of the film roll after the films were wound was 18.0 cm.

### Example 2

In Example 2, a film roll according to the present example was manufactured in the same way as in Example 1 except that instead of the winding core, the diameter of which was 3 inches (7.62 cm), a winding core having a diameter of 6 inches (15.24 cm) was used.

### Example 3

In Example 3, a film roll according to the present example was manufactured in the same way as in Example 1 except that the 50 dicing die-bonding films as described above were wound around a winding core having a diameter of 3 inches (7.62 cm), so that the diameter of the film roll after the films were wound was made into 11.3 cm.

### Example 4

In Example 4, a film roll according to the present example was manufactured in the same way as in Example 1 except that the 400 dicing die-bonding films as described above were wound around a winding core having a diameter of 3 inches (7.62 cm), so that the diameter of the film roll after the films were wound was made into 19.0 cm.

### Comparative Example 1

In Comparative Example 1, a film roll according to the present comparative example was manufactured in the same way as in Example 1 except that instead of the winding core, the diameter of which was 3 inches (7.62 cm), a winding core having a diameter of 2 inches (5.08 cm) was used.

### Comparative Example 2

In Comparative Example 2, a film roll according to the present comparative example was manufactured in the same way as in Example 1 except that the 450 dicing die-bonding films as described above were wound around a winding core having a diameter of 3 inches (7.62 cm), so that the diameter of the film roll after the films were wound was made into 20.0 cm.

### (Check of Winding Scar)

Each of the films rolls manufactured in Examples and Comparative Examples described above was stored for 1 month after the film roll was manufactured. Conditions for the storing were as follows: a temperature of 25° C., and a relative humidity of 50%. After the storing, five dicing die-bonding films nearest to the winding core were taken out from the roll. A mirror wafer (thickness: 760 μm) was mounted onto the adhesive layer of each of the dicing die-bonding films. Conditions for the mounting were as follows:

### [Attaching Conditions]

Attaching device: MA-3000 III manufactured by Nitto Seiki Co., Ltd.

Attaching speed: 10 mm/sec.

Attaching pressure: 0.15 MPa

Stage temperature at the time of the attaching: 60° C.

After the mounting, checking was conducted about whether or not a step resulting from a winding scar in the dicing die-bonding film was generated in the mirror wafer. The results are shown in Table 1 below.

### (Shore a Hardness Measurement)

The Shore A hardness concerned was measured on the basis of JIS K 6253 using a type A durometer under the conditions as follows: a thickness of 10 mm and a distance of 15 mm from an end of the test piece.

### (Results)

As is evident from Table 1 below, in the mirror wafer mounted by use of each of the dicing die-bonding films of Examples 1 to 4, a step resulting from a winding scar in the film was not observed at all; thus, it was verified that the wafer had a good external appearance. By contrast, it was verified that in each of the dicing die-bonding films of Comparative Examples 1 and 2, a step was generated in the mirror wafer.

TABLE 1

| | | | | The number | |
|---|---|---|---|---|---|
| | | | | of films in | |
| | Winding | Diameter | | which a | |
| | core | of | The | winding | |
| | diameter | film roll | number | scar was | Shore A |
| | (cm) | (cm) | of films | generated | hardness |
| Example 1 | 7.62 | 18.0 | 300 | 0 | 26 |
| Example 2 | 15.24 | 24.0 | 300 | 0 | 26 |
| Example 3 | 7.62 | 11.3 | 50 | 0 | 26 |
| Example 4 | 7.62 | 19.0 | 400 | 0 | 26 |
| Comparative | 5.08 | 16.0 | 300 | 5 | 26 |
| Example 1 | | | | | |
| Comparative | 7.62 | 20.0 | 450 | 2 | 26 |
| Example 2 | | | | | |

### DESCRIPTION OF REFERENCE NUMERALS

1: semiconductor device manufacturing film roll
2: winding core
3: dicing die-bonding film (semiconductor device manufacturing film)
11: base material
12: pressure-sensitive adhesive layer
13: adhesive layer
21: semiconductor wafer
22: semiconductor chip(s)
23: adherend
25: dicing ring
26: outside ring
27: inside ring
28: dicing blade
30: sealing resin
29: bonding wire
31: adhesive layer

1. A semiconductor device manufacturing film roll, comprising
a winding core in a cylindrical form, and
a semiconductor device manufacturing film which is wound around the winding core into a roll form,
wherein the diameter of the winding core is from 7.5 to 15.5 cm.

2. The semiconductor device manufacturing film roll according to claim 1, wherein the semiconductor device manufacturing film has a structure in which a pressure-sensitive adhesive layer, an adhesive layer, and a separator are successively laminated on a base material.

3. The semiconductor device manufacturing film roll according to claim 2, wherein the Shore A hardness of the adhesive layer is from 10 to 60 in the thickness direction of the layer, and the thickness of the adhesive layer is from 1 to 500 μm.

4. The semiconductor device manufacturing film roll according to claim 1, wherein the semiconductor device manufacturing film is wound around the winding core in the state that a winding tensile force in the range of 20 to 100 N/m is applied to the film.

5. The semiconductor device manufacturing film roll according to claim 1, which has a diameter of 8 to 30 cm.

6. The semiconductor device manufacturing film roll according to claim 2, wherein the adhesive layer comprises a thermoplastic resin and an inorganic filler.

7. The semiconductor device manufacturing film roll according to claim 2, wherein the adhesive layer comprises a thermosetting resin, and a thermoplastic resin.

8. The semiconductor device manufacturing film roll according to claim 6, wherein the thermoplastic resin is acrylic resin.

9. The semiconductor device manufacturing film roll according to claim 7, wherein the thermoplastic resin is acrylic resin.

10. The semiconductor device manufacturing film roll according to claim 7, wherein the thermosetting resin is at least either one of epoxy resin or phenolic resin.

11. The semiconductor device manufacturing film roll according to claim 2, wherein the pressure-sensitive adhesive layer comprises a ultraviolet-curable pressure sensitive adhesive.
